(19) United States
(12) Patent Application Publication
(10) Pub. No.: US 2009/0152533 A1
(43) Pub. Date: Jun. 18, 2009

(54) INCREASING THE EXTERNAL EFFICIENCY OF LIGHT EMITTING DIODES

(76) Inventors: Winston Kong Chan, Princeton, NJ (US); Viktor B. Khalfin, Highstown, NJ (US)

Correspondence Address: FOLEY & LARDNER LLP, 150 EAST GILMAN STREET, P.O. BOX 1497, MADISON, WI, 53701-1497, US

(21) Appl. No.: 11/958,172

(22) Filed: Dec. 17, 2007

(51) Int. Cl. H01L 33/00; H01L 51/00; H01L 21/02

(52) U.S. Cl. 257/40; 257/98; 438/32; 257/E51.018; 257/E33.055; 257/E21.04

(57) ABSTRACT

The present disclosure relates to increasing the external efficiency of light emitting diodes, and specifically to increasing the outcoupling of light from an organic light emitting diode utilizing a diffraction grating.

### TECHNICAL FIELD

The present disclosure relates to increasing the external efficiency of light emitting diodes, and specifically to increasing an outcoupling of light from an organic light emitting diode utilizing a diffraction grating.

### BACKGROUND

Typically an organic light-emitting diode (OLED) is a type of light-emitting diode (LED) in which the emissive layer often comprises a thin-film of certain organic compounds. The emissive electroluminescent layer can include a polymeric substance that allows the deposition of very suitable organic compounds, for example, in rows and columns on a flat carrier by using a simple “printing” method to create a matrix of pixels which can emit different colored light. Such systems can be used in television screens, computer displays, portable system screens, advertising and information, indication applications, etc. OLEDs can also be used in light sources for general space illumination. OLEDs typically emit less light per area than inorganic solid-state based LEDs which are usually designed for use as point light sources.

One of the benefits of an OLED display over the traditional LCD displays is that OLEDs typically do not require a backlight to function. This means that they often draw far less power and, when powered from a battery, can operate longer on the same charge. It is also known that OLED-based display devices can often be more effectively manufactured than liquid-crystal and plasma displays.

Prior to standardization, OLED technology was also referred to as Organic Electro-Luminescence (OEL).

As illustrated by FIG. 1, an Organic LED 100 typically includes an organic layer (or layers) 130 in addition to the substrate 110, anode 120 and cathode 140. When multiple organic sub-layers are used, two of the sub-layers are typically called the Emissive and the Conductive layers. Both these sub-layers are frequently made up of organic molecules or polymers. These selected compounds are typically labeled as Organic Semiconductors and certain conductivity levels are shown by these compounds ranging between those of insulators and conductors.

OLEDs often emit light in a similar manner to LEDs, through a process called electrophosphorescence. As the voltage is applied across the OLED such that the anode has a positive voltage with respect to the cathode, a current starts flowing through the device. The direction of conventional current flow is from anode to cathode, hence electrons flow from cathode to anode. Thus, the cathode gives electrons to the emissive layer and the anode withdraws electrons from the conductive layer (in essence, it is same as the anode giving holes to the conductive layer).

Hence, after a short time period, the emissive layer will typically become rich in negatively charged electrons while the conductive layer has an increased concentration of positively charged holes. Due to natural affinity for unlike charges, these two are attracted to each other. It is to be noted here that in organic semiconductors, in contrast to the inorganic semiconductors, the hole mobility is often greater than the mobility of electrons. Hence, as the two charges move towards each other, it is more likely that their recombination will occur in the emissive layer. Due to this recombination, there is an accompanying drop in the energy levels of the electrons and this drop is characterized by the emission of radiation with a frequency lying in the visible region, viz. light is produced. That is the reason behind this layer being called the emissive layer.

As a diode, typically the device will not work when the anode is put at a negative potential, with respect to the cathode. This is because in this condition, the anode will pull holes towards itself and the cathode will pull the electrons. Therefore, the electrons and holes are moving away from each other and will not recombine.

The external efficiency of current organic light emitting diodes (OLEDs) is frequently low. Most of the radiated light is trapped by total internal reflection in the organic layer and the anode layer, which have often higher indexes of refraction than the substrate and the surrounding air. As shown in FIG. 1, only light emitted nearly perpendicular to the layers can easily escape (paths 191 & 192). Light emitted away from perpendicular is not likely to escape. Depending on the direction of emission, the light may be trapped at the substrate-air interface (path 193), at the anode-substrate interface (path 194) or at the organic-cathode interface as a surface Plasmon (path 195). It has been estimated that about 50% of the emitted light of an OLED goes into a surface Plasmon mode. Light that does not escape is ultimately absorbed within the structure.

### BRIEF DESCRIPTION OF THE DRAWINGS

FIG. 1 is a schematic diagram illustrating an embodiment of an organic light emitting diode;

FIG. 2 is a schematic diagram illustrating an embodiment of an organic light emitting diode in accordance with the disclosure;

FIG.3 is a schematic diagram illustrating an embodiment of an organic light emitting diode in accordance with the disclosure;

FIG. 4 is a diagram illustrating an embodiment of diffraction grating patterns in accordance with the disclosure;

FIG. 5 is a diagram illustrating an embodiment of diffraction grating patterns in accordance with the disclosure;

FIG. 6 is a graph illustrating the relationship between outcoupling and grating period in accordance with the disclosure; and

FIG. 7 is a block diagram illustrating an embodiment of an apparatus and a system in accordance with the disclosure.

### DETAILED DESCRIPTION

In the following detailed description, numerous details are set forth in order to provide a thorough understanding of several embodiments. However, it will be understood by those skilled in the art that other embodiments may be practiced without these specific details. In other instances, well-known methods, procedures, components, and circuits have not been described in detail so as to not obscure claimed subject matter.

In the following detailed description, reference is made to the accompanying drawings which form a part hereof, and in which is shown by way of illustration embodiments in which the invention may be practiced. It is to be understood that other embodiments may be utilized and structural or logical changes may be made without departing from the scope of claimed subject matter. Therefore, the following detailed description is not to be taken in a limiting sense.

Various operations may be described as multiple discrete operations in turn, in a manner that may be helpful in understanding embodiments of the subject matter; however, the order of description should not be construed to imply that these operations are order dependent.

For the purposes of the description, a phrase in the form “A/B” means A or B. For the purposes of the description, a phrase in the form “A and/or B” means “(A), (B), or (A and B)”. For the purposes of the description, a phrase in the form “at least one of A, B, and C” means “(A), (B), (C), (A and B), (A and C), (B and C), or (A, B and C)”. For the purposes of the description, a phrase in the form “(A)B” means “(B) or (AB)” that is, A is an optional element.

For purposes of the description, a phrase in the form “below”, “above”, “to the right of”, etc. are relative terms and do not require the subject matter be used in any absolute orientation.

For ease of understanding, the description will be in large part presented in the context of display technology; however, claimed subject matter is not so limited, and may be practiced to provide more relevant solutions to a variety of illumination needs. Reference in the specification to a processing and/or digital “device” and/or “appliance” means that a particular feature, structure, or characteristic, namely device operable connectivity, such as the ability for the device to execute or process instructions and/or programmability, such as the ability for the device to be configured to perform designated functions, is included in at least one embodiment of the digital device as used herein. Accordingly, in one embodiment, digital devices may include general and/or special purpose computing devices, connected personal computers, network printers, network attached storage devices, voice over internet protocol devices, security cameras, baby cameras, media adapters, entertainment personal computers, and/or other networked devices suitably configured for practicing the subject matter in accordance with at least one implementation; however these are merely a few examples of processing devices to which claimed subject matter is not limited.

The description may use the phrases “in an embodiment,” or “in embodiments,” which may each refer to one or more of the same or different embodiments. Furthermore, the terms “comprising,” “including,” “having,” and the like, as used with respect to embodiments of the present invention, are synonymous.

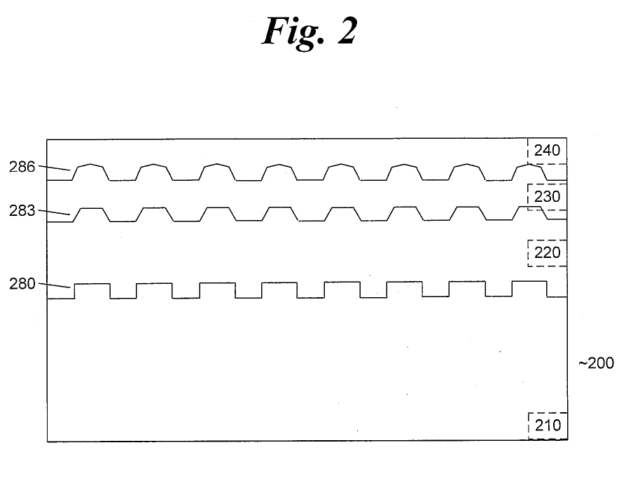

FIG. 2 is a schematic diagram illustrating an embodiment of an organic light emitting diode (OLED) 200 in accordance with the disclosure. The OLED may include a plurality of layers, such as, for example, a substrate 210, an anode layer 220, an organic layer 230, and a cathode layer 240. FIG. 2 illustrates a bottom-emitter OLED, as light is emitted through the substrate. Other embodiments may include other forms of OLEDs (not shown), such as, for example, top-emitter OLEDS (where light is emitted though a cover), a transparent OLED (where it is possible to emit light through both the top and bottom of the device), a foldable OLED (where substrates may include a very flexible metallic foil or plastics), passive-matrix OLEDs (where strips of the cathode, anode, and organic layers may be used), or active-matrix OLEDs (where a thin film transistor array may be overlayed onto the typical OLED layers), etc. In one embodiment, the organic layer(s) of the OLED may be between 100 to 500 nanometers (nm) thick.

In one embodiment, the substrate 210 may include glass, plastic, a thin film, ceramic, a semi-conductor, or a foil. Here, this substrate may be substantially optically clear, although in other embodiments an opaque material may be used. In one embodiment, the substrate may be approximately 1 millimeter (mm) thick and include an index of refraction of approximately 1.45. In one embodiment, the substrate may be capable of supporting at least one of the other layers of the LED.

In one embodiment, the anode 210 may remove electrons (i.e. add electron “holes”) when current flows through the device. In the case of the bottom-emitting OLED illustrated in FIG. 2, the anode may be substantially transparent. In some embodiments, transparent anode materials may include indium-tin oxide (ITO), indium-zinc oxide (IZO), and/or tin oxide, but other metal oxides may be used, such as, for example, aluminum-or indium-doped zinc oxide, magnesium-indium oxide, and nickel-tungsten oxide. In addition to these oxides, metal nitrides, such as gallium nitride, and metal selenides, such as zinc selenide, and metal sulfides, such as zinc sulfide, may be used as the anode in various embodiments. In other embodiments, the transmissive characteristics of the anode may be immaterial and any conductive material may be used, such as transparent, opaque or reflective materials, for example. Example conductors for these embodiments may include, but are not limited to, gold, iridium, molybdenum, palladium, and platinum. In one embodiment, the anode layer may be approximately 200 nanometers thick, and have an index of refraction of 2.

In one embodiment, the organic layer 220 may include sub-layers such as conductive and emissive layers, and, in some embodiments, a third or fourth organic layer. For this reason, the organic layer is sometimes referred to as the organic stack. These organic layers are often made of organic molecules or polymers. In one embodiment, the organic layer may be approximately 100-500 nanometers thick, and have an index of refraction of approximately 1.72.

In one embodiment, the conducting layer may be made of organic plastic molecules that transport “holes” from the anode. One conducting polymer used in OLEDs is polyaniline, although that is merely one non-limiting embodiment. The following are a few illustrative examples of possible materials that may be used various embodiments: aromatic tertiary amines, polycyclic aromatic compounds, and polymeric hole-transporting materials.

In one embodiment, the emissive layer may be made of organic plastic molecules (different ones from the conducting layer) that transport electrons from the cathode and electroluminescence is produced as a result of electron-hole pair recombination. One polymer used in some embodiments of the emissive layer is polyfluorene, although that is merely one non-limiting embodiment.

A light-emitting layer can be comprised, in one embodiment, of a single material. In other embodiments, such a light emitting layer may consist of a host material doped with a guest compound or compounds where light emission comes primarily from the dopant and can be of any color. Various dopants may be combined to produce colors. In one embodiment, this technique may be used to produce a white OLED. In one embodiment, dopants may be chosen from highly florescent dyes. In other embodiments, dopants may include phosphorescent compounds. The following are a few illustrative examples of possible materials that may be used as host materials in various embodiments: tris(8-quinolinolato)aluminum(III) (Alq3), metal complexes of 8-hydroxyquinoline (oxine) and similar derivatives, derivatives of anithracene, distyrylarylene derivatives, benzazole derivatives, or carbazole derivatives.

In various embodiments, the conducting layer and emissive layer may include a single layer. In versions of these embodiments, the emissive dopants may be added to a hole-transporting material.

In other embodiments, the organic layer 230 may also include sub-layers such as additional organic layers. In one embodiment, a hole-injecting layer may be added below or as part of the conductive layer. The hole-injecting layer, in one embodiment, may serve to improve the film formation property of subsequent organic layers and to facilitate injection of holes into the conductive layer. In another embodiment, an electron-transporting layer may be included above the emissive layer. The electron-transporting layer may, in one embodiment, help to inject and transport electrons.

In one embodiment, the cathode 240 may provide electrons (i.e. remove electron “holes”) when current flows through the device. In the case of the bottom-emitting OLED illustrated in FIG. 2, the cathode may be substantially opaque. However, in other embodiments, it may be desirable to utilize a transparent cathode. In some embodiments, cathode materials may include a lithium fluoride (LiF) layer backed by an aluminum (Al) layer, Magnesium/Silver (Mg:Ag), metal salts, or other transparent cathodes.

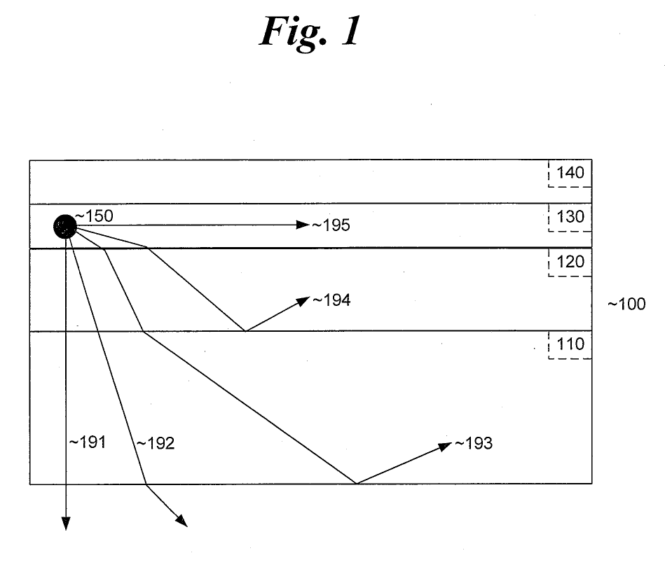

As illustrated by FIG. 1, a large portion of the light emitted by the organic layer does not leave the LED. A technique to recover this lost light is to scatter the light that emits in an unfavourable direction to a more favourable direction. Such a favourable direction would allow the light to escape the LED structure. To scatter light that would not escape (e.g. paths 193, 194, & 195) to a direction that allows it to escape (e.g. paths 191 & 192) may include the use of a diffraction grating.

Referring to FIG. 2, in one embodiment, a diffraction grating 280 may be formed on the substrate 210. In one embodiment, this diffraction grating may comprise a relief grating. This grating may be formed on the substrate-anode boundary. As the light reflects off or transmits through the diffraction grating it is likely to be outcoupled and therefore more likely to be emitted from the LED as opposed to being trapped within the LED and eventually absorbed.

In one embodiment, the substrate's diffraction grating may be transferred to the other layers of the LED. As a layer is added to the substrate, the prior diffraction grating may cause a new diffraction grating to be created on the newest top layer. For example a diffraction grating on the anode-organic layer boundary (anode's diffraction grating 283) may be derived from the substrate's diffraction grating 280. Subsequently, in one embodiment, a diffraction grating may be formed on the organic-cathode boundary (emissive layer's diffraction grating 286). This grating may also be derived from the substrate's grating via the anode's grating. It is also noted that, in one embodiment, the coupling strength of the organic-cathode boundary may be 10 times higher in comparison with the other grating patterns due to the large difference between the dielectric constants of the cathode and organic layers. In some embodiments, only one of the layers may include a grating and the other layers may not include a grating.

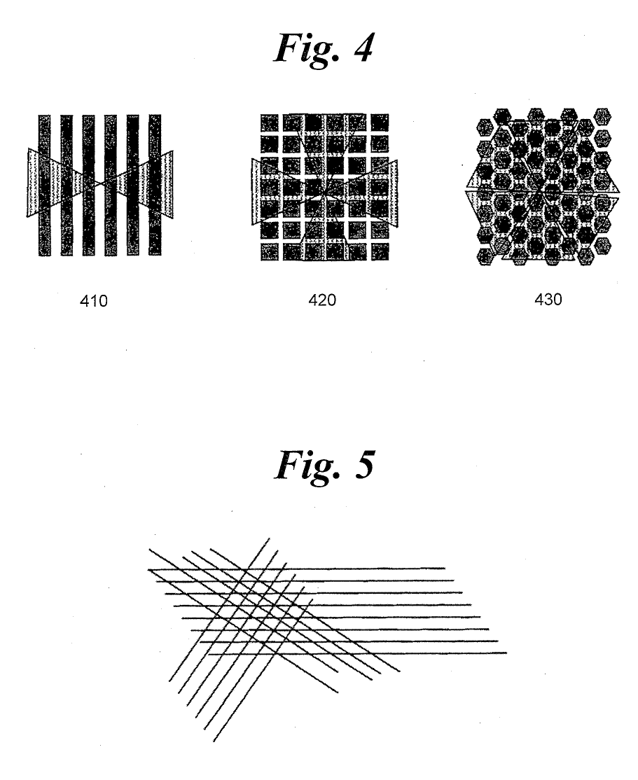

In one embodiment, the diffraction grating may include a pattern with grooves in one-dimension such as that shown in FIG. 4, 410. For an emitter at the apex of the triangles, only photons emitted in the direction of the shaded triangles may scatter in the correct direction to outcouple. Additionally or alternatively, grating 410 may comprise a series of elements distributed in an array, where the series of elements may be rectangular, hexagonal, ovoid, and/or the like in shape. In one embodiment, a double grating 420 may be used, which includes grooves in a rectangular or more generally a quadrilateral characteristic. Such a quadrilateral grating may outcouple photons emitted in the four shaded triangles. Additionally or alternatively, double grating 420 may comprise a series of elements distributed in an array, where the series of elements may be square, hexagonal, spherical, and/or the like in shape. In another embodiment, a triple grating 430 may be used. This grating may include a hexagonal pattern or characteristic. In the illustrated embodiment, a grating pattern of three series of lines inclined at 120 degree angles may be used. Once again, this hexagonal grating may outcouple photons emitted in the six shaded triangles. It can be seen that using the triple grating pattern, light emitted in almost any direction may be outcoupled from the LED. Additionally or alternatively, triple grating 430 may comprise a series of elements distributed in an array, where the series of elements may be square, hexagonal, spherical, and/or the like in shape. FIG. 5, illustrates that in some embodiments, a non-symmetrical diffraction grating pattern may be used.

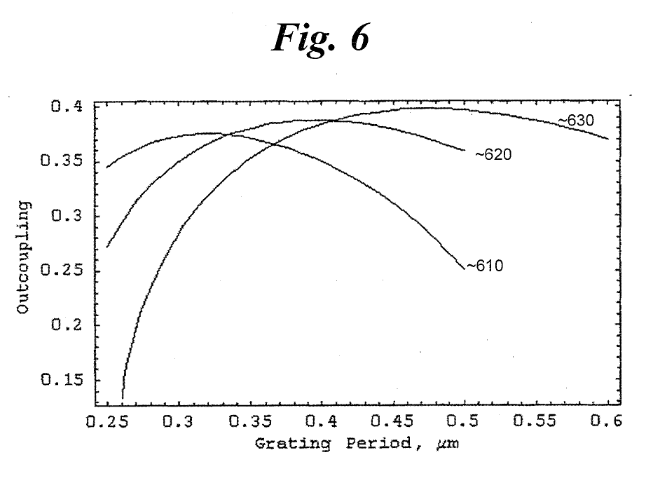

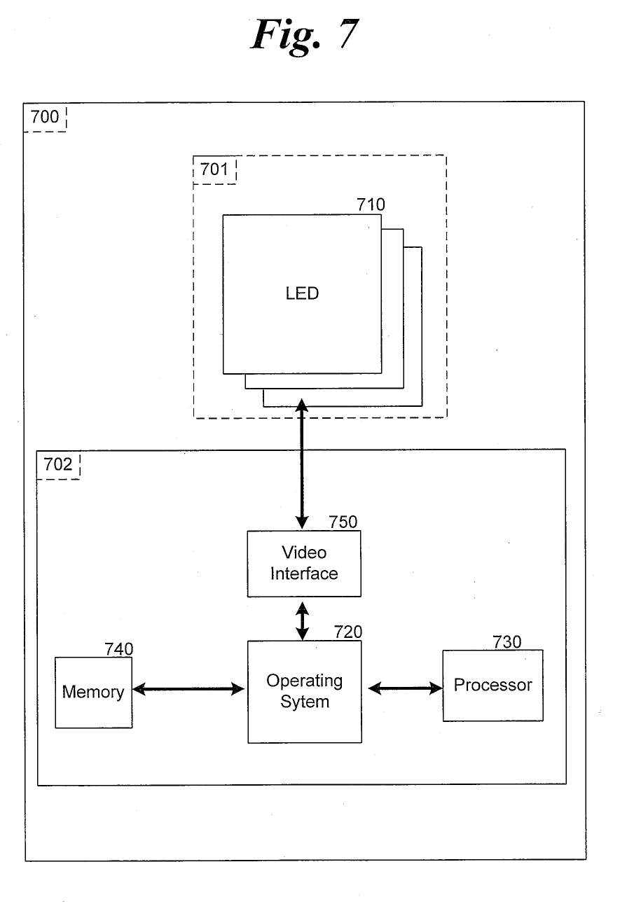

FIG. 6 illustrates, in one embodiment, the selection of the period of the diffraction grating grooves. Three wavelengths are considered. Plot 610 illustrates one embodiment of the outcoupling of the 470 nm wavelength. Plot 620 illustrates one embodiment of the outcoupling of the 560 nm wavelength. Plot 630 illustrates one embodiment of the outcoupling of the 660 nm wavelength. These are, respectively, the short, medium, and long wavelengths of light emitted by the Alq3 emission spectrum. It is understood that other organic layers may generate other outcoupling patterns.

In one embodiment, the period of the diffraction grating grooves may be selected to be substantially 0.4 microns. As illustrated by FIG. 6, this period would outcouple the most amount of emitted light for Alq3. In another embodiment, a different period corresponding to the spectrum of the emission agent and waveguide microns may be used. It is also understood that the period may not be consistent throughout the diffraction grating, LED, or total display. It is also understood that each layer's diffraction grating may include different periods.

An additional consideration is that an emitted photon be scattered before it is absorbed. This may dictate the coupling strength of the light to the grating. In one embodiment, where an aluminum cathode is used, the photon may be absorbed within 20 wavelengths. Accordingly, in one embodiment, light and grating may be strongly coupled by placing a diffraction grating at the emissive layer-cathode boundary.

Also, in one embodiment, a diffraction grating may be created with a grating period sufficiently sized to allow a photon to interact with the grating before it is absorbed. In one embodiment, the substrate's diffraction grating includes a grating period of between 10 to 20 polariton wavelengths.

In one embodiment, the diffraction grating system may increase the amount of light emitted externally from the LED by a factor of threefold as compared to a LED without the diffraction grating system. In another embodiment, the diffraction grating system may increase the efficiently of the LED from the typical 15% to 45% or 50%.

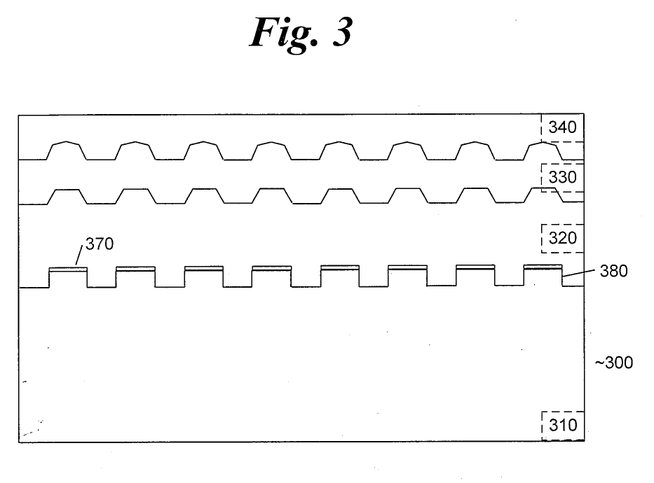

FIG. 3 is a schematic diagram illustrating an embodiment of an organic light emitting diode in accordance with the disclosure. Elements 300, 310, 320, 330, 340, and 380 are analogous to elements 200, 210, 220, 230, 240, and 280 of FIG. 2 described above. In this embodiment, a diffraction grating 380 similar to the one illustrated in FIG. 2 and described above is present. In addition metal strips 370 may be added along the ridges diffraction grating at the substrate-anode boundary. In one embodiment, the strips may be very thin, so as not to induce additional loses. In a specific embodiment, the strips may be approximately 5 nanometers thick. In one embodiment, the strips may comprise silver (Ag). However, these are merely a few non-limiting examples of metal strips that may be used for a diffraction grating.

In one embodiment, the waveguide modes and surface plasmons may be radiated in an isotropic fashion in the plane of the diffraction grating. The diffraction grating of FIG. 2 may, in one embodiment, output surface plasmons and transverse-magnetic (TM) waveguide modes because for these modes the intensity is high near the metal surface (viz. the cathode-organic boundary). In one embodiment, adding the metal strips 370 of FIG. 3 may increase the outcoupling of the (TE) modes of the waveguide at the anode-substrate boundary. Unfortunately, the Transverse-Electric (TE) modes of the waveguide have a low intensity near the metal surface. So, the diffractive grating will not output these modes efficiently.

In one embodiment, a technique for manufacturing an organic LED as described above may include the following actions. A substrate may be obtained. The substrate may, in one embodiment, have a diffraction grating etched into it. It is understood that other embodiments may exist in which etching is not used to produce the diffraction grating upon the substrate. For example, in one embodiment, the diffraction grating may be grown or applied to the substrate.

In one embodiment, a hexagonal array of polystyrene spheres that is characteristic of the triple grating illustrated by diagram 430 of FIG. 4 may be created. For example, such a hexagonal array of polystyrene spheres may comprise a single layer (or monolayer) of polystyrene spheres. This array may then be used to etch the substrate. In another embodiment, heavy ion implantation, such as for example soaking a photographically developed glass plate in a salt, may be used to form the grating. From this a surface relief etching may be made.

The other layers of the LED may then be applied or added on top of the substrate. It is contemplated that in various embodiments the layers may be formed separately and added to the substrate individually or as a preformed group. In one embodiment, these layers may be applied in order to form an embodiment of the LED illustrated in FIG. 2. In another embodiment, the layers may be applied in order to form an embodiment of the LED illustrated in FIG. 3. These layers may be applied in such a way as to allow the transfer of the substrate's diffractive grating onto the other layers. That is to say, that each layer may be applied so as to create a new diffractive grating that is substantially derived from the substrate's diffractive grating.

In one embodiment, some of the layers may be applied using a technique known as or substantially similar to vacuum deposition or vacuum thermal evaporation (VTE). In one embodiment of vacuum deposition, a vacuum chamber, the organic molecules are gently heated (evaporated) and allowed to condense as thin films onto cooled substrates.

In another embodiment, some of the layers may be applied using a technique known as or substantially similar to organic vapor phase deposition (OVPD). In one embodiment of organic vapor phase deposition, in a low-pressure, hot-walled reactor chamber, a carrier gas transports evaporated organic molecules onto cooled substrates, where they condense into thin films. Using a carrier gas may increase the efficiency and reduces the cost of making OLEDs.

In yet another embodiment, some of the layers may be applied using a technique known as or substantially similar to splattering or inkjet printing. In one embodiment, splattering may include spraying the layers onto substrates just like inks are sprayed onto paper during printing. Inkjet technology may greatly reduce the cost of OLED manufacturing and allow OLEDs to be printed onto very large films for large displays like 80-inch TV screens or electronic billboards.

It is contemplated that one or more of these techniques may be used to make or manufacture an embodiment of the disclosure. However, in other embodiments other techniques may be used. It is also contemplated that the manufacture of these embodiments may be automated.

FIG. 7 is a block diagram illustrating an embodiment of an apparatus 710 and a system 700 in accordance with the disclosure. In one embodiment, the system may include a display 701 and a processing device 702. In one embodiment, the display and processing device may be integrated, such as, for example a media device, a mobile phone, or other small form factor device.

In one embodiment, the display 701 may include at least one LED as illustrated by FIGS. 2 & 3 and discussed in detail above. In other embodiments the LEDs may include other forms of LEDs which are not bottom-emitting LEDs but include some of the features of the LEDs described above.

In one embodiment, the processing device 702 may include an operating system 720, a video interface 750, a processor 730, and a memory 740. In one embodiment, the operating system may be capable of facilitating the use of the system and generating a user interface. The processor 730 may be capable of, in one embodiment, executing or running the operating system. The memory 740 may be capable of, in one embodiment, storing the operating system. The video interface 750 may, in one embodiment, be capable of facilitating the display of the user interface and interacting with the display 701. In one embodiment, the video interface may be included within the display.

The techniques described herein are not limited to any particular hardware or software configuration; they may find applicability in any computing or processing environment. The techniques may be implemented in hardware, software, firmware or a combination thereof. The techniques may be implemented in programs executing on programmable machines such as mobile or stationary computers, personal digital assistants, and similar devices that each include a processor, a storage medium readable or accessible by the processor (including volatile and non-volatile memory and/or storage elements), at least one input device, and one or more output devices. Program code is applied to the data entered using the input device to perform the functions described and to generate output information. The output information may be applied to one or more output devices.

Each program may be implemented in a high level procedural or object oriented programming language to communicate with a processing system. However, programs may be implemented in assembly or machine language, if desired. In any case, the language may be compiled or interpreted.

Each such program may be stored on a storage medium or device, e.g. compact disk read only memory (CD-ROM), digital versatile disk (DVD), hard disk, firmware, non-volatile memory, magnetic disk or similar medium or device, that is readable by a general or special purpose programmable machine for configuring and operating the machine when the storage medium or device is read by the computer to perform the procedures described herein. The system may also be considered to be implemented as a machine-readable or accessible storage medium, configured with a program, where the storage medium so configured causes a machine to operate in a specific manner. Other embodiments are within the scope of the following claims.

While certain features of claimed subject matter have been illustrated and described herein, many modifications, substitutions, changes, and equivalents will now occur to those skilled in the art. It is, therefore, to be understood that the appended claims are intended to cover all such modifications and changes that fall within the true spirit of claimed subject matter.

The following is claimed:

1. An apparatus comprising:
a light emitting diode (LED) including:
an emissive layer capable of emitting light, and
a substrate having a diffraction grating, wherein the substrate's diffraction grating is capable of at least in part directing a scattering of light emitted by the emissive layer.

2. The apparatus of claim 1, further comprising:
an anode having a diffraction grating derived, at least in part, from the substrate's diffractive grating and wherein the anode's diffraction grating is capable of at least in part directing the scattering of light emitted by the emissive layer, and
wherein the anode is disposed substantially between the emissive layer and the substrate.

3. The apparatus of claim 1, wherein the light emitting diode includes an organic light emitting diode.

4. The apparatus of claim 1, the substrate's diffractive grating comprises a transmission diffractive grating.

5. The apparatus of claim 2, wherein the anode includes a layer of indium tin oxide (ITO).

6. The apparatus of claim 4, wherein the emissive layer includes a layer of Tris-8-Hydroxyquinoline Aluminum (Alq₃).

7. The apparatus of claim 4, further comprising a cathode, wherein the emissive layer is disposed substantially between the cathode and an anode, and the cathode does not include a diffractive grating.

8. The apparatus of claim 1, wherein the substrate includes glass.

9. The apparatus of claim 1, wherein the diffraction grating is at least partially etched onto the substrate.

10. The apparatus of claim 1, wherein the diffraction grating further comprises a plurality of gratings.

11. The apparatus of claim 10, wherein the diffraction grating includes a double grating pattern having a substantially quadrilateral characteristic.

12. The apparatus of claim 10, wherein the diffraction grating includes a triple grating pattern having a substantially hexagonal characteristic.

13. The apparatus of claim 1, wherein a period of the substrate's diffraction grating is sized to be capable of facilitating the outcoupling of the emitted light.

14. The apparatus of claim 13, wherein the substrate's diffraction grating includes a grating period of between 0.3 microns and 0.6 microns, inclusive.

15. The apparatus of claim 14, wherein the substrate's diffraction grating includes a grating period of substantially 0.4 microns.

16. The apparatus of claim 13, wherein an average dimension of a grating period of substrate's diffraction grating includes a grating period greater than 10 polariton wavelengths.

17. The apparatus of claim 16, wherein the average dimension of a grating period of substrate's diffraction grating includes a grating period of between 10 to 20 polariton wavelengths.

18. The apparatus of claim 13, wherein an average outcoupling of light in the light emitting diode is at least three times greater than it would be without the diffraction grating.

19. The apparatus of claim 13, wherein an external efficiency of the light emitting diode is at least 45%.

20. A system comprising:
an operating system capable of facilitating the use of the system, and generating a user interface;
a processor capable of running the operating system; and
a display capable of displaying the user interface, and including at least one light emitting diode (LED) having:
an emissive layer capable of emitting light, and
a substrate having a first diffraction grating component, wherein the substrate's diffraction grating is capable of at least in part directing the scattering of light emitted by the emissive layer.

21. The system of claim 20, wherein the display further comprises:
an anode having a second diffraction grating component derived, at least in part, from the first diffraction grating component and wherein the second diffraction grating component is capable of at least in part directing the scattering of light emitted by the emissive layer, and
wherein the anode is disposed substantially between the emissive layer and the substrate.

22. A method of making a light emitting diode (LED) comprising:
forming a first diffraction grating on a substrate, wherein the first diffraction grating is capable of at least in part directing the scattering of light emitted by an emissive layer; and
applying a plurality of layers to the substrate,
wherein one of the plurality of layers includes the emissive layer which is capable of emitting light, and
wherein one of the plurality of layers includes an anode having a second diffraction grating derived, at least in part, from the substrate's first diffractive grating and wherein the anode's second diffraction grating is capable of at least in part directing the scattering of light emitted by the emissive layer.

23. The method of claim 22, wherein the first diffraction grating is at least partially etched onto the substrate.

24. The method of claim 23, wherein etching the first diffraction grating includes creating a monolayer array of polystyrene spheres that is characteristic of the desired diffraction grating pattern; and
utilizing the monolayer array of polystyrene spheres to facilitate the etching of the substrate.

25. The method of claim 24, wherein the monolayer array of polystyrene spheres includes a hexagonal array of polystyrene spheres.

26. The method of claim 22, wherein the first diffraction grating comprises a plurality of gratings.

27. The method of claim 26, wherein the first diffraction grating includes a double grating pattern having a substantially quadrilateral characteristic.

28. The method of claim 26, wherein the first diffraction grating includes a triple grating pattern having a substantially hexagonal characteristic.

29. A light emitting diode (LED) comprising:
an emissive means for emitting light,
a first diffraction means for directing the scattering of light emitted by the emissive means, and
a second diffraction means for directing the scattering of light emitted by the emissive means, wherein said second diffraction means is derived, at least in part, from said first diffraction means, and wherein the second diffraction means is disposed substantially between said emissive means and said first diffraction means.
